(19) United States
(12) Patent Application Publication
(10) Pub. No.: US 2024/0345168 A1
(43) Pub. Date: Oct. 17, 2024

(54) METHOD OF CONTROLLING BATTERY AND BATTERY POWER CONVERSION APPARATUS

(71) Applicants: Hyundai Motor Company, Seoul (KR); Kia Corporation, Seoul (KR)

(72) Inventor: Tae Il YEAM, Ulsan (KR)

(73) Assignees: Hyundai Motor Company, Seoul (KR); Kia Corporation, Seoul (KR)

(21) Appl. No.: 18/373,210

(22) Filed: Sep. 26, 2023

(30) Foreign Application Priority Data
Apr. 17, 2023 (KR) 10-2023-0050093

(51) Int. Cl. G01R 31/367; B60L 58/12; B60L 58/18; G01R 31/3842

(52) U.S. Cl. CPC G01R 31/367; B60L 58/12; B60L 58/18; G01R 31/3842; B60L 2210/10

(57) ABSTRACT

A method of controlling a battery includes: identifying an estimated state of charge (SOC) value of a first battery based on a measured current of the first battery; setting an output voltage command value of a direct current (DC)/DC converter, which adjusts a voltage of a second battery and outputs the adjusted voltage to the first battery, based on the estimated SOC value; and adjusting the estimated SOC value based on the estimated SOC value and the output voltage command value.

### CROSS REFERENCE TO RELATED APPLICATION

The present application claims priority to Korean Patent Application No. 10-2023-0050093, filed on Apr. 17, 2023, the entire contents of which is incorporated herein for all purposes by this reference.

### BACKGROUND OF THE PRESENT DISCLOSURE

### Field of the Present Disclosure

The present disclosure relates to a method of correcting an estimated state of charge (SOC) value of a battery and a battery power conversion apparatus.

### Description of Related Art

An electrified vehicle may include a direct current (DC) converter such as a low voltage DC-DC converter (LDC) to step down the voltage of a high voltage battery and supply power to electrical loads and an auxiliary battery, and a controller to control the output voltage of the LDC.

The controller may control the output voltage of the LDC based on the state of charge (SOC) value of the auxiliary battery. For example, when the SOC value of the auxiliary battery is low, the controller may adjust the output voltage of the LDC to be higher than the voltage of the auxiliary battery so that the auxiliary battery may be charged. On the other hand, when the SOC value of the auxiliary battery is high, the controller may adjust the output voltage of the LDC to be lower than the voltage of the auxiliary battery so that the auxiliary battery may be discharged.

The SOC value of a battery may be estimated based on coulomb counting. Here, coulomb counting refers to a technique used to estimate the SOC value of a battery by integrating current flowing in the battery to obtain a change in the SOC value and adding the obtained change to an initial SOC.

In general, the initial SOC may be estimated according to the voltage and temperature of the battery based on a lookup table (LUT). In the instant case, if the initial SOC is incorrectly estimated, the voltage of the high voltage battery associated with the LDC is unstably controlled, resulting in decrease in the power efficiency (ex. MPGe, Miles per gallon of gasoline-equivalent) of the electrified vehicle.

The information included in this Background of the present disclosure is only for enhancement of understanding of the general background of the present disclosure and may not be taken as an acknowledgement or any form of suggestion that this information forms the prior art already known to a person skilled in the art.

### BRIEF SUMMARY

Various aspects of the present disclosure are directed to correcting a measured state of charge (SOC) value of a battery based on results of monitoring the current of the battery while driving to reduce an SOC error of the battery, improving the fuel efficiency of an electrified vehicle, and stabilizing voltage control of the battery.

Technical problems to be solved in the present disclosure are not limited to the forementioned technical problems, and other unmentioned technical problems may be clearly understood from the following description by a person having ordinary knowledge in the art to which the present disclosure pertains.

According to an exemplary embodiment of the present disclosure, a method of controlling a battery include: identifying an estimated state of charge (SOC) value of a first battery based on a measured current of the first battery: setting an output voltage command value of a direct current (DC)/DC converter, which adjusts a voltage of a second battery and outputs the adjusted voltage to the first battery, based on the estimated SOC value; and adjusting the estimated SOC value based on the estimated SOC value and the output voltage command value.

For example, the identifying of the estimated SOC may include: identifying an initial SOC value of the first battery: identifying a change in SOC value of the first battery by integrating the measured current of the first battery; and setting a value, which is obtained by adding the change in SOC value to the initial SOC value, as the estimated SOC.

For example, the identifying of the initial SOC may include setting the initial SOC value based on an open circuit voltage (OCV) and a temperature of the first battery with reference to a lookup table (LUT).

For example, the identifying of the change in SOC may include setting the change in SOC value by dividing the integrated measured current by capacity of the first battery.

For example, the setting of the output voltage command value may include: adjusting the output voltage command value to discharge the first battery when the estimated SOC is higher than a reference level; and adjusting the output voltage command value to charge the first battery when the estimated SOC is lower than the reference level.

For example, the adjusting of the estimated SOC may be performed when the measured current is maintained below a preset measured level for a preset time period.

For example, the adjusting of the estimated SOC may include: adjusting the estimated SOC to become lower when the estimated SOC is within a first set range and the output voltage command value is lower a first set value; and adjusting the estimated SOC to become higher when the estimated SOC is within a second set range and the output voltage command value is higher than a second set value, and the first set range may be set to be higher than the second set range, and the first set value may be set to be lower than the second set value.

For example, the method may further include: up-counting an error flag value whenever the estimated SOC is adjusted; and maintaining the output voltage command value at a predetermined value when the error flag value exceeds a preset value.

For example, the method may further include outputting an error state about the first battery to an external device when the error flag value exceeds the preset value.

According to another exemplary embodiment of the present disclosure, a battery power conversion apparatus includes: a first battery; a second battery; a direct current (DC)/DC converter connected between the first and second batteries and configured to adjust and output a voltage of the second battery to the first battery; and a controller configured to identify an estimated state of charge (SOC) value of the first battery based on a measured current of the first battery, set an output voltage command value of the DC-DC converter based on the estimated SOC value, and adjust the estimated SOC value based on the estimated SOC value and the output voltage command value.

For example, the controller may be configured to set the estimated SOC by adding a change in SOC value, which is identified by integrating the measured current, to an initial SOC value of the first battery.

For example, the controller may be configured to set the initial SOC value based on the OCV and temperature of the first battery with reference to an LUT.

For example, the controller may be configured to set the change in SOC value by dividing the integrated measured current by capacity of the first battery.

For example, the controller may be configured to adjust the output voltage command value to discharge the first battery when the estimated SOC is higher than a reference level, and adjust the output voltage command value to charge the first battery when the estimated SOC is lower than the reference level.

For example, the controller may be configured to adjust the estimated SOC when the measured current is maintained below a preset measured level for a preset time period.

For example, the controller may be configured to adjust the estimated SOC to become lower when the estimated SOC is within a first set range and the output voltage command value is lower than a first set value, and adjust the estimated SOC to become higher when the estimated SOC is within a second set range and the output voltage command value is higher than a second set value, the first set range may be set to be higher than the second set range, and the first set value may be set to be lower than the second set value.

For example, the controller may be configured to up-count an error flag value whenever the estimated SOC is adjusted, and maintain the output voltage command value at a predetermined value when the error flag value exceeds a preset value.

For example, the controller may be configured to output an error state about the first battery to an external device when the error flag value exceeds the preset value.

As described above, a measured state of charge (SOC) value of a battery is corrected based on the results of monitoring the current of the battery while driving to reduce an SOC error of the battery, improving the fuel efficiency of an electrified vehicle, and stabilizing voltage control of the battery.

Effects obtainable from the present disclosure may not be limited by the aforementioned effects, and other unmentioned effects may be clearly understood from the following description by a person having ordinary knowledge in the art to which the present disclosure pertains.

The methods and apparatuses of the present disclosure have other features and advantages which will be apparent from or are set forth in more detail in the accompanying drawings, which are incorporated herein, and the following Detailed Description, which together serve to explain certain principles of the present disclosure.

### BRIEF DESCRIPTION OF THE DRAWINGS

FIG. 1 is a block diagram of a power conversion apparatus included in an electrified vehicle according to an exemplary embodiment of the present disclosure.

FIG. 2 is a flowchart for describing a method of operating a power conversion apparatus according to an exemplary embodiment of the present disclosure.

It may be understood that the appended drawings are not necessarily to scale, presenting a somewhat simplified representation of various features illustrative of the basic principles of the present disclosure. The predetermined design features of the present disclosure as included herein, including, for example, specific dimensions, orientations, locations, and shapes will be determined in part by the particularly intended application and use environment.

In the figures, reference numbers refer to the same or equivalent portions of the present disclosure throughout the several figures of the drawing.

### DETAILED DESCRIPTION

Reference will now be made in detail to various embodiments of the present disclosure(s), examples of which are illustrated in the accompanying drawings and described below. While the present disclosure(s) will be described in conjunction with exemplary embodiments of the present disclosure, it will be understood that the present description is not intended to limit the present disclosure(s) to those exemplary embodiments of the present disclosure. On the other hand, the present disclosure(s) is/are intended to cover not only the exemplary embodiments of the present disclosure, but also various alternatives, modifications, equivalents and other embodiments, which may be included within the spirit and scope of the present disclosure as defined by the appended claims.

Hereinafter, various embodiments of the present disclosure will be described in detail with reference to the accompanying drawings, in which a same or similar elements are denoted by a same reference numerals even though they are depicted in different drawings and redundant descriptions thereof will be avoided.

In terms of describing the exemplary embodiments of the present disclosure, detailed descriptions of related art will be omitted when they may make the subject matter of the exemplary embodiments of the present disclosure rather unclear. Furthermore, the accompanying drawings are provided only for a better understanding of the exemplary embodiments of the present disclosure and are not intended to limit technical ideas of the present disclosure. Therefore, it should be understood that the accompanying drawings include all modifications, equivalents and substitutions within the scope and spirit of the present disclosure.

In the description of the following embodiments, the term “preset” means that the numerical value of a parameter is determined in advance when the parameter is used in a process or algorithm. According to various exemplary embodiments of the present disclosure, the numerical value of a parameter may be set when a process or algorithm starts or may be set during a period in which the process or algorithm is executed.

Terms such as “first” and “second” may be used to describe various components, but the components should not be limited by the above terms. Furthermore, the above terms are used only for distinguishing one component from another.

When it is described that one component is “connected” or “joined” to another component, it should be understood that the one component may be directly connected or joined to another component, but additional components may be present therebetween. However, when one component is described as being “directly connected,” or “directly coupled” to another component, it should be understood that additional components may be absent between the one component and another component.

Unless the context clearly dictates otherwise, singular forms include plural forms as well.

In an exemplary embodiment of the present disclosure, it should be understood that term “include” or “have” indicates that a feature, a number, a step, an operation, an element, a part, or the combination thereof described in the exemplary embodiments is present, but does not preclude a possibility of presence or addition of one or more other features, numbers, steps, operations, elements, parts or combinations thereof, in advance.

The controller may include a communication device that communicates with other controllers or sensors, to control its own functions, a memory that stores an operating system, logic commands, and input and output information, and one or more processors that perform identification, calculation, determination, and the like, which is necessary for the control of the function which is responsible therefor.

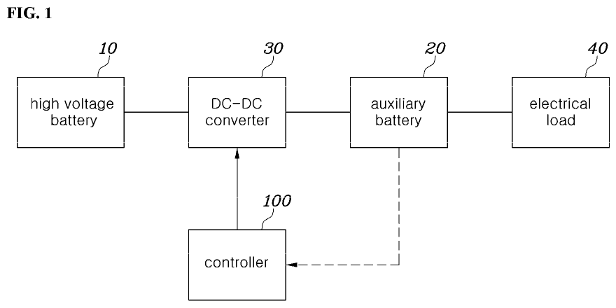

FIG. 1 is a block diagram of a power conversion apparatus included in an electrified vehicle according to an exemplary embodiment of the present disclosure.

Referring to FIG. 1, a power conversion apparatus of an electrified vehicle may include a high-voltage battery 10, an auxiliary battery 20, a direct current (DC)-DC converter 30 connected between the high voltage battery 10 and the auxiliary battery 20, an electrical load 40, and a controller 100.

The high voltage battery 10 refers to an energy source for driving a motor of the electrified vehicle, and may have a higher voltage than the auxiliary battery 20. The auxiliary battery 20 may be provided to supply power to the electrical load 40.

The DC-DC converter 30 may adjust the voltage of the high voltage battery 10 and output the adjusted voltage to the auxiliary battery 20. In more detail, the DC-DC converter 30 may be implemented by a low DC-DC converter (LDC) that steps down the voltage of the high voltage battery 10 and outputs the step-down voltage to the auxiliary battery 20.

The controller 100 may be configured to determine an output voltage command value for the DC-DC converter 30 based on an estimated state of charge (SOC) value of the auxiliary battery 20, and adjust the output voltage of the DC-DC converter 30 by switching a switching element included in the DC-DC converter 30 according to the determined output voltage command value.

First, the controller 100 may identify the estimated SOC value of the auxiliary battery 20 by coulomb counting based on measured current of the auxiliary battery 20. In more detail, as shown in the following equation 1, the controller 100 may set the estimated SOC (SOC_{Aux_bat}) by adding a change in

$$SOC ( \int n \frac{{i}_{Aux \_ bat}}{{Q}_{Aux \_ bat}} dt )$$

of the auxiliary battery 20, which is obtained by integrating the measured current (i_{Aux_bat}) of the auxiliary battery 20, to an initial SOC (SOCᵢₙᵢₜ) of the auxiliary battery 20.

$${SOC}_{Aux \_ bat} = {SOC}_{init} + \int n \frac{{i}_{Aux \_ bat}}{{Q}_{Aux \_ bat}} dt \qquad Equation 1$$

In the instant case, the initial SOC (SOCᵢₙᵢₜ) of the auxiliary battery 20 may be set by the controller 100 according to the open circuit voltage (OCV) of the auxiliary battery 20 and the temperature of the auxiliary battery 20 with reference to a look-up table (LUT).

Furthermore, the change in

$$SOC ( \int n \frac{{i}_{Aux \_ bat}}{{Q}_{Aux \_ bat}} dt )$$

of the auxiliary battery 20 may be set by the controller 100 based on the charging and discharging efficiency (n) of the auxiliary battery 20, a value (∫i_{Aux_bat}dt) obtained by integrating the current of the auxiliary battery 20 measured for a predetermined time period, and the capacity (Q_{Aux_bat}) of the auxiliary battery 20. In more detail, the controller 100 may divide the integrated measured current (∫i_{Aux_bat}dt) by the capacity (Q_{Aux_bat}) of the auxiliary battery 20 and multiply the quotient by the charging and discharging efficiencies (n) to set the change in

$$SOC ( \int n \frac{{i}_{Aux \_ bat}}{{Q}_{Aux \_ bat}} dt ) .$$

Accordingly, the controller 100 may set the output voltage command value of the DC-DC converter 30, based on the estimated SOC value of the auxiliary battery 20. In more detail, when the estimated SOC value of the auxiliary battery 20 is higher than a reference level, the controller 100 may adjust the output voltage command value of the DC-DC converter 30 to be lower than the voltage of the auxiliary battery 20 so that the auxiliary battery 20 may be discharged, supplying the power of the auxiliary battery 20 to the electrical loads 40. On the other hand, when the estimated SOC value of the auxiliary battery 20 is lower than the reference level, the controller 100 may adjust the output voltage command value of the DC-DC converter 30 to become high so that the auxiliary battery 20 may be charged, supplying the power of the high voltage battery 10 to the auxiliary battery 20 and the electrical loads 40. In the instant case, the reference level may be variously set according to various exemplary embodiments of the present disclosure.

Accordingly, the controller 100 may adjust the estimated SOC value of the auxiliary battery 20, based on the results of monitoring the measured current of the auxiliary battery 20 and the output voltage command value of the DC-DC converter 30.

In more detail, the controller 100 may monitor the measured current of the auxiliary battery 20, and identify that a condition for adjusting the estimated SOC value of the auxiliary battery 20 is satisfied when the measured current of the auxiliary battery 20 is maintained below a preset measured level (e.g., 90 A) for a preset time period (e.g., for 900 seconds).

In the case where it is determined that the condition for adjusting the estimated SOC is satisfied, the controller 100 may adjust the estimated SOC value of the auxiliary battery 20 to become lower when the estimated SOC value of the auxiliary battery 20 is within a first set range and the output voltage command value of the DC-DC converter 30 is lower than a first set value, and adjust the estimated SOC value of the auxiliary battery 20 to become higher when the estimated SOC value of the auxiliary battery 20 is within a second set range and the output voltage command value of the DC-DC converter 30 is higher than a second set value. In the instant case, the first set range may be set to be higher than the second set range, and the first set value may be set to be lower than the second set value.

The controller 100 may up-count an error flag value by ‘I’ whenever the estimated SOC value of the auxiliary battery 20 is adjusted, and maintain the output voltage command value of the DC-DC converter 30 at a predetermined value (e.g., 14.2 V) and output an error state about the auxiliary battery 20 to an external device (e.g., a cluster of the electrified vehicle) when the error flag value exceeds a preset value (e.g., 10).

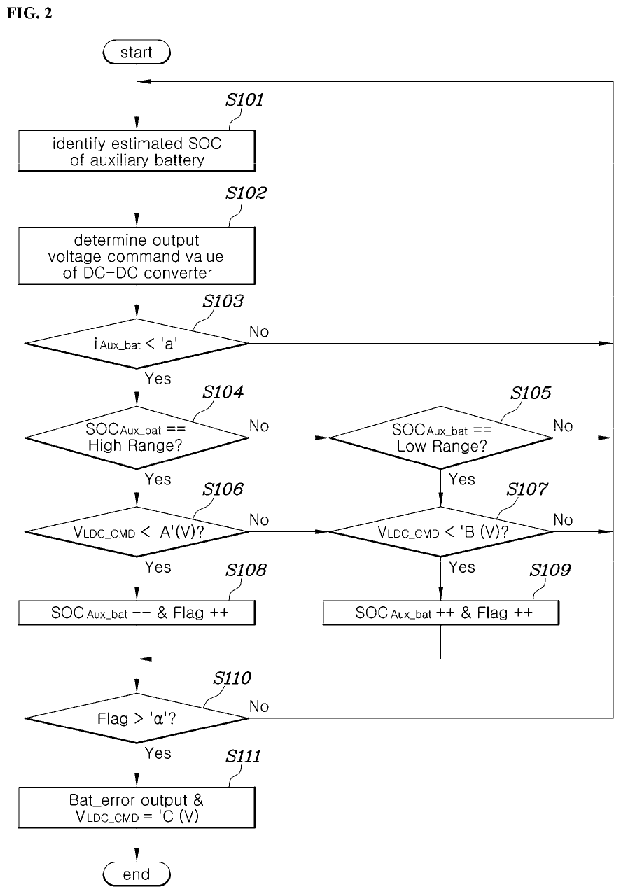

FIG. 2 is a flowchart for describing a method of operating a power conversion apparatus according to an exemplary embodiment of the present disclosure.

Referring to FIG. 2, the controller 100 may identify the estimated SOC value of the auxiliary battery 20 by the coulomb counting based on the measured current of the auxiliary battery 20 (S101), and determine the output voltage command value of the DC-DC converter 30 based on the estimated SOC value of the auxiliary battery 20 (S102).

Accordingly, the controller 100 may identify whether the condition for adjusting the estimated SOC value of the auxiliary battery 20 is satisfied, based on whether the measured current (i_{Aux_bat}) of the auxiliary battery 20 is maintained below a preset measured level (“a”, e.g., 90 A) for a preset time period (e.g., for 900 seconds) (S103).

In the case where it is determined that the condition for adjusting the estimated SOC is satisfied (YES in S103), the controller 100 may identify whether the estimated SOC (SOC_{Aux_bat}) of the auxiliary battery 20 is within the first set range (High Range) (S104) and identify whether the estimated SOC (SOC_{Aux_bat}) of the auxiliary battery 20 is within the second set range (Low Range) (S105).

When the estimated SOC (SOC_{Aux_bat}) of the auxiliary battery 20 is within the first set range (High Range) (YES in S104), the controller 100 may identify whether the output voltage command value (V_{LDC_CMD}) of the DC-DC converter 30 is lower than the first set value (‘A’) (S106). When the output voltage command value (V_{LDC_CMD}) is lower than the first set value (‘A’) (YES in S106), the controller 100 adjusts the estimated SOC (SOC_{Aux_bat}) of the auxiliary battery 20 to become lower and up-counts the error flag value (S108).

When the estimated SOC (SOC_{Aux_bat}) of the auxiliary battery 20 is within the second set range (Low Range) (YES in S105), the controller 100 may identify whether the output voltage command value (V_{LDC_CMD}) of the DC-DC converter 30 is higher than the second set value (‘B’) (S107). When the output voltage command value (V_{LDC_CMD}) is higher than the second set value (‘B’) (YES in S107), the controller 100 adjusts the estimated SOC (SOC_{Aux_bat}) of the auxiliary battery 20 to become higher and up-counts the error flag value (S109).

Here, the first set range (High Range) is set to be higher than the second set range (Low Range) and the first set value (‘A’) is lower than the second set value (‘B’).

Accordingly, the controller 100 may identify whether the error flag value exceeds a preset value (α) (S110).

When the error flag value exceeds the preset value (α) (YES in S110), the controller 100 may output an error state (Bat error) of the auxiliary battery 20, and maintain the output voltage command value (V_{LDC_CMD}) of the DC-DC converter 30 at a third set value (‘C’) (S111).

Meanwhile, the foregoing disclosure may be implemented as a computer-readable code in a medium where a program is recorded. The computer-readable medium includes any types of recording devices in which data readable by a computer system is stored. As examples of the computer-readable medium, there are a Hard Disk Drive (HDD), a solid-state disk (SSD), a silicon disk drive (SSD), a read only memory (ROM), a random-access memory (RAM), a compact disc (CD)-ROM, a magnetic tape, a floppy disk, optical storage device, etc.

Furthermore, the term related to a control device such as “controller”, “control apparatus”, “control unit”, “control device”, “control module”, or “server”, etc refers to a hardware device including a memory and a processor configured to execute one or more steps interpreted as an algorithm structure. The memory stores algorithm steps, and the processor executes the algorithm steps to perform one or more processes of a method in accordance with various exemplary embodiments of the present disclosure. The control device according to exemplary embodiments of the present disclosure may be implemented through a nonvolatile memory configured to store algorithms for controlling operation of various components of a vehicle or data about software commands for executing the algorithms, and a processor configured to perform operation to be described above using the data stored in the memory. The memory and the processor may be individual chips. Alternatively, the memory and the processor may be integrated in a single chip. The processor may be implemented as one or more processors. The processor may include various logic circuits and operation circuits, may be configured to process data according to a program provided from the memory, and may be configured to generate a control signal according to the processing result.

The control device may be at least one microprocessor operated by a predetermined program which may include a series of commands for carrying out the method included in the aforementioned various exemplary embodiments of the present disclosure.

The aforementioned invention can also be embodied as computer readable codes on a computer readable recording medium. The computer readable recording medium is any data storage device that can store data which may be thereafter read by a computer system and store and execute program instructions which may be thereafter read by a computer system. Examples of the computer readable recording medium include Hard Disk Drive (HDD), solid state disk (SSD), silicon disk drive (SDD), read-only memory (ROM), random-access memory (RAM), CD-ROMs, magnetic tapes, floppy discs, optical data storage devices, etc and implementation as carrier waves (e.g., transmission over the Internet). Examples of the program instruction include machine language code such as those generated by a compiler, as well as high-level language code which may be executed by a computer using an interpreter or the like.

In various exemplary embodiments of the present disclosure, each operation described above may be performed by a control device, and the control device may be configured by a plurality of control devices, or an integrated single control device.

In various exemplary embodiments of the present disclosure, the memory and the processor may be provided as one chip, or provided as separate chips.

In various exemplary embodiments of the present disclosure, the scope of the present disclosure includes software or machine-executable commands (e.g., an operating system, an application, firmware, a program, etc.) for enabling operations according to the methods of various embodiments to be executed on an apparatus or a computer, a non-transitory computer-readable medium including such software or commands stored thereon and executable on the apparatus or the computer.

In various exemplary embodiments of the present disclosure, the control device may be implemented in a form of hardware or software, or may be implemented in a combination of hardware and software.

Furthermore, the terms such as “unit”, “module”, etc. included in the specification mean units for processing at least one function or operation, which may be implemented by hardware, software, or a combination thereof.

For convenience in explanation and accurate definition in the appended claims, the terms “upper”, “lower”, “inner”, “outer”, “up”, “down”, “upwards”, “downwards”, “front”, “rear”, “back”, “inside”, “outside”, “inwardly”, “outwardly”, “interior”, “exterior”, “internal”, “external”, “forwards”, and “backwards” are used to describe features of the exemplary embodiments with reference to the positions of such features as displayed in the figures. It will be further understood that the term “connect” or its derivatives refer both to direct and indirect connection.

The term “and/or” may include a combination of a plurality of related listed items or any of a plurality of related listed items. For example, “A and/or B” includes all three cases such as “A”, “B”, and “A and B”.

In the present specification, unless stated otherwise, a singular expression includes a plural expression unless the context clearly indicates otherwise.

In exemplary embodiments of the present disclosure, “at least one of A and B” may refer to “at least one of A or B” or “at least one of combinations of one or more of A and B”. In addition, “one or more of A and B” may refer to “one or more of A or B” or “one or more of combinations of one or more of A and B”.

In the exemplary embodiment of the present disclosure, it should be understood that a term such as “include” or “have” is directed to designate that the features, numbers, steps, operations, elements, parts, or combinations thereof described in the specification are present, and does not preclude the possibility of addition or presence of one or more other features, numbers, steps, operations, elements, parts, or combinations thereof.

The foregoing descriptions of specific exemplary embodiments of the present disclosure have been presented for purposes of illustration and description. They are not intended to be exhaustive or to limit the present disclosure to the precise forms disclosed, and obviously many modifications and variations are possible in light of the above teachings. The exemplary embodiments were chosen and described in order to explain certain principles of the invention and their practical application, to enable others skilled in the art to make and utilize various exemplary embodiments of the present disclosure, as well as various alternatives and modifications thereof. It is intended that the scope of the present disclosure be defined by the Claims appended hereto and their equivalents.

What is claimed is:

1. A method of controlling a battery, the method comprising:
identifying, by a controller, an estimated state of charge (SOC) value of a first battery based on a measured current of the first battery;
setting, by the controller, an output voltage command value of a direct current (DC)-DC converter, which adjusts a voltage of a second battery and outputs the adjusted voltage to the first battery, based on the estimated SOC value; and
adjusting, by the controller, the estimated SOC value based on the estimated SOC value and the output voltage command value.

2. The method of claim 1, wherein the identifying of the estimated SOC includes:
identifying an initial SOC value of the first battery;
identifying a change in SOC value of the first battery by integrating the measured current of the first battery; and
setting a value, which is obtained by adding the change in SOC value to the initial SOC value, as the estimated SOC.

3. The method of claim 2, wherein the identifying of the initial SOC includes setting the initial SOC value based on an open circuit voltage (OCV) and a temperature of the first battery with reference to a lookup table (LUT).

4. The method of claim 2, wherein the identifying of the change in SOC includes setting the change in the SOC value by dividing the integrated measured current by a capacity of the first battery.

5. The method of claim 1, wherein the setting of the output voltage command value includes:
adjusting the output voltage command value to discharge the first battery upon the estimated SOC being higher than a reference level; and
adjusting the output voltage command value to charge the first battery upon the estimated SOC being lower than the reference level.

6. The method of claim 1, wherein the adjusting of the estimated SOC is performed upon the measured current being maintained below a preset measured level for a preset time period.

7. The method of claim 1, wherein the adjusting of the estimated SOC includes:
adjusting the estimated SOC to become lower upon the estimated SOC being within a first set range and the output voltage command value being lower than a first set value; and
adjusting the estimated SOC to become higher upon the estimated SOC being within a second set range and the output voltage command value being higher than a second set value, and
the first set range is set to be higher than the second set range, and
the first set value is set to be lower than the second set value.

8. The method of claim 1, further including:
up-counting an error flag value whenever the estimated SOC is adjusted; and
maintaining the output voltage command value at a predetermined value upon the error flag value exceeding a preset value.

9. The method of claim 8, further including outputting an error state about the first battery to an external device upon the error flag value exceeding the preset value.

10. A non-transitory computer readable storage medium on which a program for performing the method of claim 1 is recorded.

11. A battery power conversion apparatus comprising:
a first battery;
a second battery;
a direct current (DC)-DC converter connected between the first and second batteries and configured to adjust and output a voltage of the second battery to the first battery; and
a controller configured to identify an estimated state of charge (SOC) value of the first battery based on a measured current of the first battery, set an output voltage command value of the DC-DC converter based on the estimated SOC VALUE, and adjust the estimated SOC value based on the estimated SOC value and the output voltage command value.

12. The battery power conversion apparatus of claim 11, wherein the controller is configured to set the estimated SOC by adding a change in SOC value, which is identified by integrating the measured current, to an initial SOC value of the first battery.

13. The battery power conversion apparatus of claim 12, wherein the controller is configured to set the initial SOC value based on an open circuit voltage (OCV) and a temperature of the first battery with reference to a lookup table (LUT).

14. The battery power conversion apparatus of claim 12, wherein the controller is configured to set the change in SOC value by dividing the integrated measured current by a capacity of the first battery.

15. The battery power conversion apparatus of claim 11, wherein the controller is configured to adjust the output voltage command value to discharge the first battery upon the estimated SOC being higher than a reference level, and adjust the output voltage command value to charge the first battery upon the estimated SOC being lower than the reference level.

16. The battery power conversion apparatus of claim 11, wherein the controller is configured to adjust the estimated SOC upon the measured current being maintained below a preset measured level for a preset time period.

17. The battery power conversion apparatus of claim 11,
wherein the controller is configured to adjust the estimated SOC to become lower upon the estimated SOC being within a first set range and the output voltage command value being lower than a first set value, and adjust the estimated SOC to become higher upon the estimated SOC being within a second set range and the output voltage command value being higher than a second set value,
wherein the first set range is set to be higher than the second set range, and
wherein the first set value is set to be lower than the second set value.

18. The battery power conversion apparatus of claim 11, wherein the controller is configured to up-count an error flag value whenever the estimated SOC is adjusted, and maintain the output voltage command value at a predetermined value upon the error flag value exceeding a preset value.

19. The battery power conversion apparatus of claim 18, wherein the controller is configured to output an error state about the first battery to an external device upon the error flag value exceeding the preset value.
